(19) United States
(12) Patent Application Publication
(10) Pub. No.: US 2025/0031352 A1
(43) Pub. Date: Jan. 23, 2025

(54) COOLING SYSTEM FOR A DRIVING DEVICE OF A HYBRID OR ELECTRIC VEHICLE AND DRIVING DEVICE WITH SUCH A COOLING SYSTEM

(71) Applicant: ZF Friedrichshafen AG, Friedrichshafen (DE)

(72) Inventors: Tobias Zürn, Tettnang (DE); Arthur Strehlau, Friedrichshafen (DE)

(73) Assignee: ZF Friedrichshafen AG, Friedrichshafen (DE)

(21) Appl. No.: 18/778,243

(22) Filed: Jul. 19, 2024

(30) Foreign Application Priority Data
Jul. 21, 2023 (DE) 10 2023 206 959.8

(51) Int. Cl. H05K 7/20

(52) U.S. Cl. CPC H05K 7/20927; H05K 7/20272

(57) ABSTRACT

A cooling system for a drive assembly in a hybrid or electric vehicle includes a reservoir that contains and supplies fluid for a first coolant circuit, which is conveyed by a pump from a sump into an interior of a housing for the reservoir, wherein there is at least one coolant line for a second coolant circuit on and/or in the housing with which coolant is conveyed from power electronics to a heat exchanger.

### CROSS-REFERENCE TO RELATED APPLICATION

This application claims priority to German Application No. 10 2023 206 959.8, filed on Jul. 21, 2023, the entirety of which is hereby fully incorporated by reference herein.

### FIELD

The present disclosure relates to a cooling system for a drive assembly in a hybrid or electric vehicle, and a drive assembly that has such a cooling system.

### BACKGROUND

Hybrid and electric vehicles that are powered with an electric axle normally contain an electric machine, power electronics, and possibly a transmission, which are cooled with a heat exchanger. A cooling system for the electric axle can contain at least one coolant circuit, which is normally designed to cool a transmission and a rotor in an electric machine in the hybrid or electric vehicle. There can be another coolant circuit for cooling the power electronics and the stator in the electric machine in the hybrid or electric vehicle. The power electronics are normally actively cooled by plate coolers. A plate cooler is a special type of heat exchanger normally composed of corrugated plates that are placed together such that the medium that is to be heated and then release heat flows in the successive spaces therebetween.

DE 10 2018 213 394 A1 discloses a cooler for an electric axle that has a first coolant circuit for cooling a transmission and a rotor in an electric machine in the hybrid or electric vehicle, and a second coolant circuit with which an inverter for the electric axle and a stator in the electric machine in the hybrid or electric vehicle are cooled. There is at least one temperature sensor with which the temperature of the transmission, the rotor in the electric machine for the hybrid or electric vehicle, the inverter for the electric axle, or the stator in the electric machine for the hybrid or electric vehicle is detected. There is also a pump assembly powered by an electric machine that has first and second pumps connected by a shaft. The first pump is used to pump coolant through the first coolant circuit, and the second pump pumps coolant through the second circuit. The electric machine can be controlled with the temperature detected by the at least one temperature sensor.

### SUMMARY

An object of the present disclosure is to create a cooling system that cools a drive assembly more effectively. The problem is solved with the subject matter of the present disclosure. The present disclosure also describes preferred embodiments.

The cooling system for a drive assembly in a hybrid or electric vehicle contains a reservoir that collects and provides fluid for a first coolant circuit, which is conveyed from a sump to an interior of a housing for the reservoir by a pump, with at least one coolant line for a second coolant circuit on and/or in the housing, which conveys coolant from the power electronics to a heat exchanger. The interior is at least partially delimited by the housing for the reservoir, and is designed such that a sufficient amount of fluid is collected in the reservoir and can be stored for supplying thermal elements or other components, for example.

The pump is part of a hydraulic system, preferably in the form of a vane pump, which is at least indirectly powered by an electric motor to draw fluid in the first coolant circuit from the sump and convey it to the reservoir. The reservoir is a dry sump reservoir in particular, also referred to as a storage tank. If the fluid in the first coolant circuit is a type of oil, the reservoir can also be regarded as an oil tank.

The fluid can be conveyed from the reservoir by at least one other pump in a hydraulic system for cooling or lubricating thermal elements or other components of a motor vehicle. In other words, the reservoir supplies coolant to the thermal elements or other components. The other pump can be powered, along with the pump that conveys fluid from the sump to the reservoir, by the aforementioned electric motor. The two pumps can also be functionally connected by a drive shaft. The other pump can also be powered by a separate electric motor. After the thermal elements or components have been supplied with fluid from the first coolant circuit, the fluid is returned to the sump with the appropriate device or method and in a fundamentally known manner, from where the fluid can again be conveyed to the reservoir.

The reservoir is formed by the housing, which can be made of a single piece or numerous pieces. The material from which the reservoir or housing is made can be adapted to the requirements for the cooling system. The housing can conceivably be made of a light metal in order to reduce the overall weight of the vehicle. The reservoir is preferably made in a casting process.

By conveying the fluid from the sump into the reservoir, a necessary fluid level is constantly maintained in the reservoir, or interior of the housing, to ensure that there is always enough fluid available for the thermal elements.

At least part of the at least one coolant line for the second coolant circuit passes through the interior of the housing in one exemplary embodiment, such that at least part of the outer surface of the at least one coolant line remains in contact with the fluid in the interior of the housing. This coolant line is therefore substantially a tube in one exemplary embodiment, and at least part of it passes through the interior of the housing such that this at least one coolant line is at least partially surrounded by the fluid in the interior of the housing. This allows the coolant in the coolant line to absorb heat from the fluid present in and/or flowing into the reservoir.

The first coolant circuit is designed to cool a transmission and a rotor for an electric machine in the hybrid or electric vehicle. The first coolant circuit is also a lubricant circuit, in particular if transmission components such as gears, shafts or bearings are lubricated by the first coolant circuit.

The second coolant circuit is designed to cool power electronics in the hybrid or electric vehicle, and a stator in the electric machine for the hybrid or electric vehicle. The power electronics is part of a power electronics module in the electric machine for the hybrid or electric vehicle, and is designed to operate, i.e. control and regulate, the electric machine. The power electronics assembly can contain an inverter or the like, which is cooled by the second coolant circuit.

The at least one coolant line can be formed by a hose or tube, etc. The at least one coolant line is preferably made of a material with which heat can be effectively exchanged between the coolant in the second coolant circuit and the fluid for the first coolant circuit in the reservoir, e.g. copper or aluminum. The coolant can be water or some other conventional coolant. If water is used for the coolant, the fluid in the first coolant circuit is water cooled.

The at least one coolant line can be connected to an upstream plate cooler for the power electronics. After the power electronics have been cooled, the coolant is conveyed through the at least one coolant line to the heat exchanger where the fluid heated by the drive assembly is then cooled.

The size of the heat exchanger depends on the necessary cooling capacity. Because the coolant flows through the reservoir, the fluid can discharge heat or be cooled in the housing, as a result of which the heat exchanger does not have to be as large as in the prior art.

The at least one coolant line can take the shortest path through the interior of the housing, from one side to the other. Alternatively, the at least one coolant line can wind back and forth to increase its length through the interior of the housing. The length of the coolant line can depend on the placement of the power electronics, reservoir, and/or heat exchanger in the vehicle.

At least part of one or more coolant lines can pass through the housing. All of the explanations given above for the at least one coolant line also apply to other coolant lines, parts of which also pass through the reservoir. Because the coolant is conducted through the reservoir, the fluid in the first coolant circuit can release some of its heat therein.

An access line to the first coolant circuit is preferably placed on the reservoir such that fluid can be exchanged between the interior of the housing and the pump. The fluid in the first coolant circuit is conveyed by the pump through the access line into the interior of the housing. The access line is therefore to be understood as an inlet into the reservoir. The access line can be a simple hole or opening into the housing for the reservoir, which opens into the housing at the top, bottom or side thereof. The access line can also be a tube or hose, at least part of which passes through the interior of the housing and conveys the fluid in the desired manner to where it is needed.

In an alternative exemplary embodiment, the access line is designed to accommodate at least a segment of the at least one coolant line in that the inner diameter of the access line, at least where it accommodates the at least one coolant line, is greater than the outer diameter thereof. This results in a double-walled tube segment in at least part of the coolant line, where the at least one coolant line is surrounded by the fluid in the first coolant circuit within the access line, and where the fluid in the first coolant circuit conveyed by the access line is first conveyed along the at least one coolant line before it subsequently enters the interior of the housing for the reservoir. Consequently, the fluid is already cooled in the access line. The access line has an inlet or intake and outlet or drain, with the inlet directed toward the pump and the outlet directed toward the interior of the housing.

The inlet and outlet of the access line are placed in relation to the direction in which the coolant flows through the at least one coolant line such that the fluid flows in the opposite direction of the coolant. This results in a counterflow, further improving heat exchange.

In another version of the present disclosure, the access line is coaxial to the at least one coolant line, at least where it is encompasses the at least one coolant line. When both the access line and coolant line have a circular cross section, the segment of the coolant line passing through the access line is surrounded evenly on all sides by fluid in the first coolant circuit, such that a uniform heat exchange is obtained between the fluid and the coolant.

The at least one coolant line can also have ridges, recesses, projections and/or grooves on the side exposed to the fluid in the first coolant circuit, thus increasing the surface area in contact with this fluid in the housing. By increasing the contact surface area of the at least one coolant line, a more effective heat exchange is obtained between the fluid in the first coolant circuit and the coolant in the second coolant circuit, such that the heat exchanger and/or plate cooler can be thinner or smaller. In one exemplary embodiment, the at least one coolant line can have cooling fins that increase the surface area of the at least one coolant line where it comes in contact with the fluid in the first coolant circuit, thus improving the cooling effect.

The ridges, recesses, projections and/or grooves can be part of the at least one coolant line, or be a separate component, which is then connected to the at least one coolant line for heat exchange. The projections can form a heat sink, e.g. in the form of so-called “pin-fin” elements, which are on the surface of the at least one coolant line exposed to the fluid in the first coolant circuit.

In another embodiment, the at least one coolant line forms an opening, hole, and/or cut-out in the housing for the reservoir. This coolant line can therefore be formed by a hole in the housing for the reservoir. This also allows the fluid in the first coolant circuit to release heat to the coolant through the coolant conductor on the housing. With this design, the at least one coolant line can be easily formed during the casting process for the housing.

The drive assembly for a hybrid or electric vehicle according to the present disclosure contains the cooling system described herein. The drive assembly can contain an electrically powered axle, or electric drive train for an axle in the hybrid or electric vehicle. The drive assembly can contain an electric machine and an optional transmission, with which torque is obtained for powering the at least one drive wheel for the hybrid or electric vehicle. In addition to an electric machine, there can also be an electric control unit, which can also be cooled with coolant in the second coolant circuit. The drive assembly can also contain a battery that supplies electricity to the electric machine.

The present disclosure shall be explained below in greater detail in reference to the drawings.

### BRIEF DESCRIPTION OF THE DRAWINGS

FIG. 1 shows a drive assembly according to the present disclosure in a motor vehicle, which has a first embodiment of a cooling system according to the present disclosure;

FIG. 2a shows a longitudinal sectional view of a reservoir for the cooling system according to the present disclosure shown in FIG. 1;

FIG. 2b shows a cross sectional view of the reservoir in the cooling system according to the present disclosure shown in FIGS. 1 and 2a;

FIG. 3a shows a longitudinal sectional view of a second embodiment of the reservoir in the cooling system according to the present disclosure;

FIG. 3b shows a cross sectional view of the reservoir in the cooling system according to the present disclosure shown in FIG. 3a; and

FIG. 4 shows a cross sectional view of a third embodiment of the reservoir in the cooling system according to the present disclosure.

### DETAILED DESCRIPTION

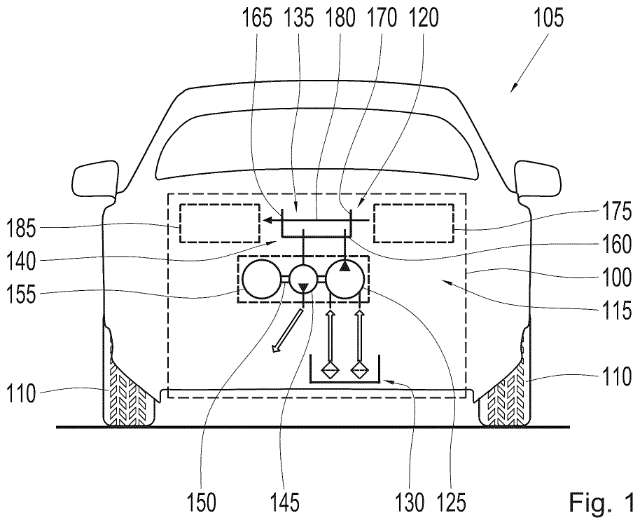

FIG. 1 shows a drive assembly 100 according to the present disclosure, in a vehicle according to the present disclosure, which can be an electric or hybrid vehicle 105. Depending on the design of the vehicle, it can either be purely electric or partially electric and partially powered by an internal combustion engine. The drive assembly 100 is designed to power at least one drive wheel 110 for the electric vehicle 105. An electric machine can be used for this, not shown in the drawings, which is supplied with electricity from a battery. There can also be a transmission—also not shown in the drawings—with which mechanical energy is supplied to the drive wheel 110. The transmission can also be powered by a drive machine, e.g. a piston engine, thus resulting in a hybrid vehicle. There can also be a differential, not shown in the drawings, which transfers power to both drive wheels 110 on the axle shown in FIG. 1.

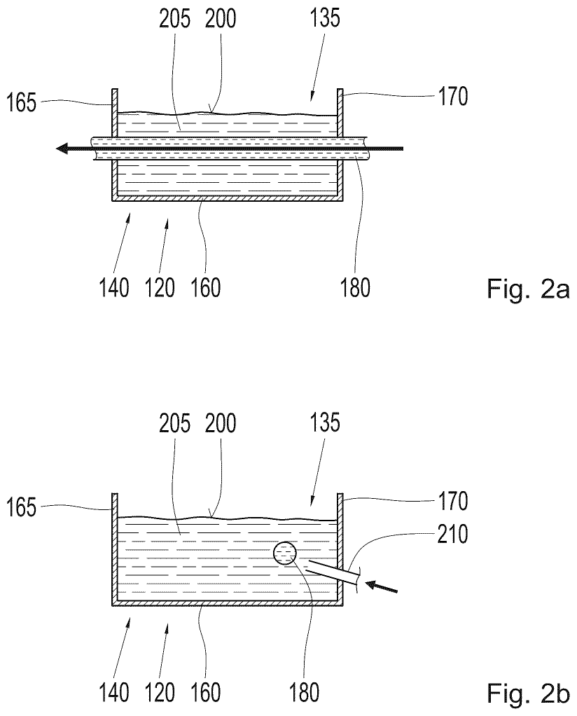

The electric or hybrid vehicle 105 also contains a cooling system 115 according to the present disclosure, three different embodiments of which are described below in reference to FIGS. 2a to 4. The cooling system 115 can be part of a hydraulic system for cooling and lubricating thermal elements—not shown—in the electric vehicle 105, which shall not be described in greater detail herein.

The cooling system 115 contains a reservoir 120 that stores and supplies fluid for a first coolant circuit. The fluid can be conveyed by a pump 125, in the form of a vane pump, in the hydraulic system from a sump 130, in this case an oil pan, into the interior 135 of a housing 140 for the reservoir 120, in order to continuously provide enough fluid for cooling and lubricating components when in use. The reservoir 120 can also be part of the hydraulic system, and provides fluid that can be supplied to at least one other pump 145 in order to supply the components with fluid, i.e. coolant and/or lubricant. The fluid preferred for use in the present disclosure is oil.

The first pump 125 and second pump 145 are connected by the same shaft 150 to an electric motor 155, which drives both pumps 125, 145.

The housing 140 has a base 160 and side walls 165, 170, and is open at the top in the drawings. There can also be a lid, not shown, resulting in a fully enclosed interior 135 in the housing 140. The housing 140 in the present case is obtained in a casting process.

The cooling system 115 contains a second coolant circuit, which cools power electronics 175 for the drive assembly 100, in particular a plate cooler in a power module. Fluid can be conveyed between the power electronics 175 and a second heat exchanger 185 by a coolant line 180 for the second coolant circuit in the form of a tube. Only one coolant line 180 is shown in FIGS. 1 to 3b, although there can conceivably be more coolant lines, as shown in FIG. 4. All of the explanations regarding the coolant line 180 also apply to any other coolant lines.

In a first embodiment, shown in in FIGS. 1 to 2b, the coolant line 180 extends substantially horizontally between two opposing side walls 165, 170 of the housing 140, through which coolant flows in the direction of the arrow in FIGS. 1 and 2a from right to left, below the level 200 of the fluid in the interior 135 of the housing 140. The coolant line 180 is also placed in the housing 140 such that it is always below the level 200 of the fluid in the interior 135 of the housing 140, and is constantly surrounded by this fluid 205.

The cross-sectional view of the reservoir 120 shown in FIG. 2b shows an access line 210 through which the fluid conveyed by the pump 125 flows into the reservoir. The access line 210 for the first coolant circuit thus connects the interior 135 of the housing 140 to the pump 125. The access line 210 is placed and oriented in relation to the coolant line 180 such that the fluid conveyed by the pump 125 in the first coolant circuit is directed toward the coolant line 180, thus generating turbulence at and around the coolant line 185 while the fluid is conveyed to the reservoir 120, thus improving the heat exchange between the fluid 205 in the first coolant circuit and the coolant in the second coolant circuit. This improves the cooling effect of the system proposed herein, such that the heat exchanger 180 and/or plate cooler for the power electronics 175 can be smaller than those in cooling systems from the prior art. Existing devices and methods for filling the reservoir can therefore be used or improved, in order to obtain turbulences surrounding the coolant conductors.

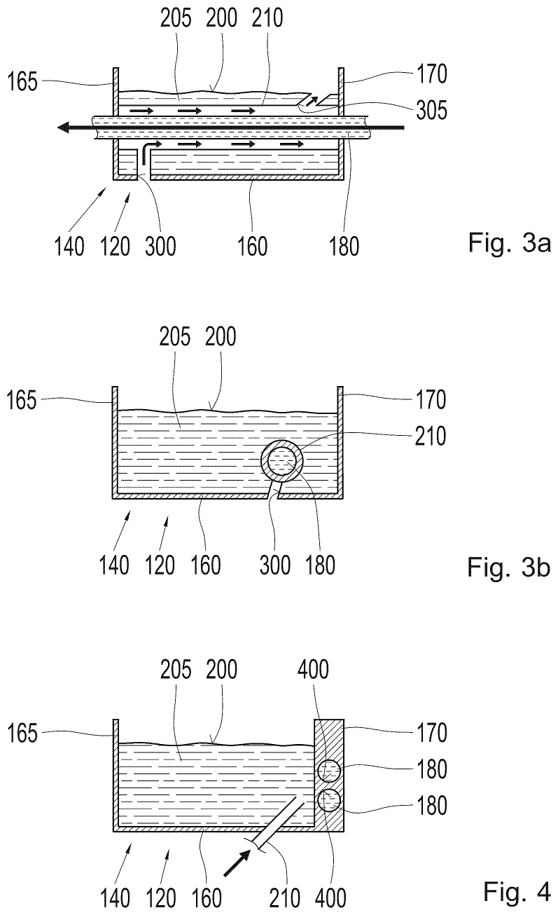

FIGS. 3a and 3b show a second embodiment of the cooling system 115, of which only the differences to the first embodiment, shown in FIGS. 1 to 2b, shall be explained below.

The access line 210 encompasses a segment of the coolant line 180 between the side walls 165, 170 and is coaxial thereto. The outer diameter of the coolant line 180 is smaller than the inner diameter of the access line 210, such that an annular gap is formed therebetween, through which the fluid 205 in the first coolant circuit flows in the direction of the arrow from an inlet 300, shown in FIGS. 3a and 3b, to an outlet 305, shown in FIG. 3a, before entering the interior 135 of the housing 140. The arrows in the access line 210, which substantially point toward the right, and the arrows in the coolant line 180, which point toward the left, illustrate how the coolant in the second coolant circuit and the fluid in the first coolant circuit flow in opposite directions, thus reducing the cooling capacity needed from the heat exchanger 185. This also results in a double-walled coolant conveyance.

FIG. 4 shows how the third embodiment does not require the coolant line 180 to be a tube passing through the fluid 205 in the interior 135 of the housing 140, and instead, the cooling effect can already be improved when the coolant line 180 is simply an opening, hole, and/or cut-out in the housing 140 for the reservoir 120. Furthermore, the superimposed circles, or holes 400, in the side wall 170 of the housing on the right show how there can be more than one coolant line 180. The access line 210 is analogous to that in FIG. 2b, to which reference is made in this regard.

The coolant line 180 in all of the exemplary embodiments can have ridges, recesses, projections and/or grooves on the side facing the first coolant circuit, i.e. on the outside, such that the surface area of the outside of the coolant line 180 that comes in contact with the fluid 205 in the first coolant circuit is increased. In particular, the outer surface area of the coolant line 180 can be increased by pin-fin elements.

The present disclosure is not limited to the embodiments disclosed herein. Other embodiments or variations can be derived by the person skilled in the art when using the present disclosure and analyzing the drawings, description and claims. In particular, the exemplary embodiments shown here can be combined with one another to optimize the cooling effect of the system and thus obtain a thinner, more compact, and therefore less expensive heat exchanger 185 and/or cooling elements for the power electronics 175.

### REFERENCE SYMBOLS

100 drive assembly
105 electric vehicle
110 drive wheel
115 cooling system
120 reservoir
125 pump
130 sump
135 interior
140 housing
145 pump
150 shaft
155 electric motor
160 base
165 side wall
170 side wall
175 power electronics
180 coolant line
185 heat exchanger
200 fluid level
205 fluid
210 access line
300 inlet
305 outlet
400 hole

1. A cooling system for a drive assembly in a hybrid or electric vehicle, comprising:
a reservoir that contains and supplies fluid for a first coolant circuit, which is conveyed by a pump from a sump into an interior of a housing for the reservoir,
wherein there is at least one coolant line for a second coolant circuit on and/or in the housing with which coolant is conveyed from power electronics to a heat exchanger.

2. The cooling system according to claim 1, comprising:
an access line for the first coolant circuit on the reservoir, with which the fluid can be exchanged between the interior of the housing and the pump.

3. The cooling system according to claim 2,
wherein the access line is configured to accommodate at least a segment of the at least one coolant line,
wherein an inner diameter of the access line is greater than an outer diameter of the at least one coolant line, at least at the segment of the at least one coolant line where it is accommodated in the access line.

4. The cooling system according to claim 3,
wherein the access line is coaxial to the at least one coolant line, at least at the segment of the at least one coolant line where it is accommodated in the access line.

5. The cooling system according to claim 1,
wherein the at least one coolant line is tube-shaped,
wherein at least part of the at least one coolant line passes through the interior of the housing, and
wherein the at least one coolant line is at least partially surrounded by the fluid for the first coolant circuit in the interior of the housing.

6. The cooling system according to claim 5, comprising:
an access line for the first coolant circuit on the reservoir, with which the fluid can be exchanged between the interior of the housing and the pump,
wherein the access line is positioned and oriented in relation to the at least one coolant line such that the fluid in the first coolant circuit flows toward the at least one coolant line.

7. The cooling system according to claim 1,
wherein the at least one coolant line comprises ridges, recesses, projections, and/or grooves on a side exposed to the fluid in the first coolant circuit, and which are configured to increase a surface area that comes in contact with the fluid in the first coolant circuit in the interior of the housing.

8. The cooling system according to claim 1,
wherein the at least one coolant line forms an opening, hole, and/or cut-out in the housing for the reservoir.

9. The cooling system according to claim 1,
wherein the housing is a cast housing.

10. A drive assembly for a hybrid or electric vehicle, comprising:
the cooling system according to claim 1.
